(19) United States
(12) Patent Application Publication
(10) Pub. No.: US 2015/0332783 A1
(43) Pub. Date: Nov. 19, 2015

(54) METHOD OF OPERATING SEMICONDUCTOR DEVICE

(71) Applicant: SK hynix Inc., Gyeonggi-do (KR)

(72) Inventor: Yeon Joo JEONG, Chungcheongbuk-do (KR)

(21) Appl. No.: 14/475,187

(22) Filed: Sep. 2, 2014

(30) Foreign Application Priority Data
May 14, 2014 (KR) 10-2014-0058000

(51) Int. Cl. G11C 16/34; G11C 16/14

(52) U.S. Cl. CPC G11C 16/3459; G11C 16/14; G11C 16/3445

(57) ABSTRACT

A method of operating a semiconductor device includes programming a first cell, verifying a second cell adjacent to the first cell, and repeating the programming of the first cell and the verifying of the second cell until the verifying of the second cell passes.

### CROSS-REFERENCE TO RELATED APPLICATION

The present application claims priority to Korean patent application number 10-2014-0058000, filed on May 14, 2014, the entire disclosure of which is incorporated herein in its entirety by reference.

### BACKGROUND

1. Field of Invention

Various exemplary embodiments of the present invention relate generally to a method of operating a semiconductor device and, more particularly, to a program operation of selection transistors.

2. Description of Related Art

Semiconductor devices are classified into two-dimensional memory devices and three-dimensional memory devices, depending on the memory cell string configurations.

The two-dimensional memory device includes a cell string in which memory cells are arranged parallel to each other over a semiconductor substrate. The three-dimensional memory device includes a cell string in which memory cells are arranged in a vertical direction to the semiconductor substrate.

Cell strings of two-dimensional or three-dimensional memory devices include selection transistors in addition to memory cells. For example, a single cell string is coupled between a bit line and a common source line, and includes a plurality of memory cells, a drain selection transistor, and a source selection transistor coupled to both ends of the memory cells. A drain of the drain selection transistor is coupled to the bit line, and a source of the source selection transistor is coupled to the common source line.

As the size of semiconductor devices is reduced, the degree of integration of the semiconductor devices is increased. This increase in degree of integration may affect electrical characteristics of the semiconductor devices, and deteriorate the reliability thereof. For example, as the degree of integration of a semiconductor device increases, the size of memory cells and selection transistors may be reduced. The decrease in size of respective elements may result in a decrease in voltage level and current used in each operation. When the voltage and current are reduced, the sensing level of verify and read operations performed during program and erase operations may be reduced. Thus, a more accurate sensing operation may be required.

Among the elements constituting the cell string, electrical characteristics (for example, potential) of drain and source selection transistors may affect sensing operations. For example, voltage or current transferred to the bit line may vary depending on threshold voltage levels of the drain and source selection transistors.

However, since increased integration means decreased drain and source selection transistor size, threshold voltages of the drain and source selection transistors included in different cell strings may be different. This difference in threshold voltage between the drain and source selection transistors may occur in both three-dimensional and two-dimensional semiconductor devices.

As described above, non-uniform electrical characteristics of drain and source selection transistors included in a plurality of cell strings may cause deterioration in program, erase and read operations of semiconductor devices.

### SUMMARY

Exemplary embodiments of the present invention are directed to a semiconductor device with improved reliability, a system including the semiconductor device, and a method of operating the same.

A method of operating a semiconductor device according to an embodiment of the present invention may include programming a first cell, verifying a second cell adjacent to the first cell, and repeating the programming of the first cell, and the verifying of the second cell until the verifying of the second cell passes.

A method of operating a semiconductor device including a memory block having a plurality of cell strings comprising dummy cells coupled between selection transistors and memory cells according to an embodiment of the present invention may include programming the dummy cells when an erase operation on the memory block is completed, verifying the selection transistors, and repeating the programming of the dummy cells and the verifying of the selection transistors until the verifying of the selection transistors passes.

A method of operating a semiconductor device including a memory block having a plurality of cell strings comprising dummy cells coupled between selection transistors and memory cells according to an embodiment of the present invention may include performing an erase operation on the memory block, reducing a density of first electrons in a channel region adjacent to the selection transistors, performing a verify operation on the selection transistors, and repeating the reducing of the density and the performing of the verify operation until the verify operation passes.

### BRIEF DESCRIPTION OF THE DRAWINGS

FIG. 1 is a block diagram illustrating a semiconductor device according to an embodiment of the present invention;

FIG. 2 is a circuit diagram illustrating a two-dimensional memory cell string;

FIGS. 3A and 3B are cross-sectional views illustrating the memory cell string shown in FIG. 2;

FIG. 4 is a circuit diagram illustrating a three-dimensional memory cell string according to an embodiment of the present invention;

FIG. 5 is a circuit diagram illustrating a three-dimensional memory cell string according to another embodiment of the present invention;

FIGS. 6A and 6B are cross-sectional views illustrating the memory cell string shown in FIG. 4 or 5;

FIG. 7 is a flowchart illustrating an operating method of a semiconductor device according to an embodiment of the present invention;

FIG. 8 is a schematic view illustrating the movement of electrons during a program operation of a dummy cell according to an embodiment of the present invention;

FIG. 9 is a block diagram illustrating a solid state drive including a semiconductor device according to an embodiment of the present invention;

FIG. 10 is a block diagram illustrating a memory system including a semiconductor device according to an embodiment of the present invention; and

FIG. 11 is a schematic view illustrating a computing system including a semiconductor device according to an embodiment of the present invention.

### DETAILED DESCRIPTION

Hereinafter, various embodiments of the present invention will be described in detail with reference to the accompanying drawings. The figures are provided to enable those of ordinary skill in the art to make and use the present invention. Throughout the disclosure, like reference numerals correspond directly to the like numbered parts in the various figures and embodiments.

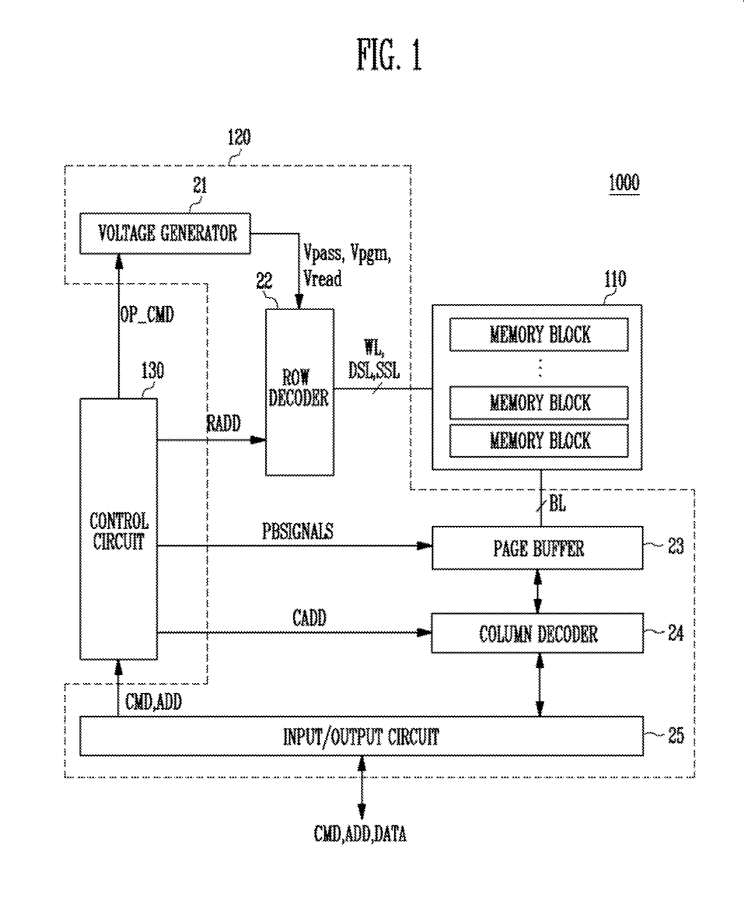

FIG. 1 is a block diagram illustrating a semiconductor device according to an embodiment of the present invention.

Referring to FIG. 1, a semiconductor device 1000 may include a memory cell array 110 for storing data, a circuit group 120 for performing program, read and erase operations on the memory cell array 110, and a control circuit 130 for controlling the circuit group 120.

The memory cell array 110 may include a plurality of memory blocks. The memory blocks may have substantially the same configuration as each other. Each of the memory blocks may include a plurality of cell strings (not illustrated). Each of the cell strings may have a two-dimensional structure or a three-dimensional structure. A nonvolatile memory device including two-dimensional cell strings may be classified as a two-dimensional nonvolatile memory device. A nonvolatile memory device including three-dimensional cell strings may be classified as a three-dimensional nonvolatile memory device.

The circuit group 120 may include a voltage generator 21, a row decoder 22, a page buffer 23, a column decoder 24 and an input/output circuit 25.

The voltage generator 21 may generate operating voltages having various levels in response to an operating command signal OP_CMD. The operating command signal OP_CMD may include a program command signal, a read command signal and an erase command signal. For example, the voltage generator 21 may generate a program voltage Vpgm, a read voltage Vread, a pass voltage Vpass, and other voltages having various levels.

The row decoder 22 may select one of the memory blocks included in the memory cell array 110 in response to a row address RADD, and transfer operating voltages to word lines WL, drain selection lines DSL and source selection lines SSL coupled to a selected memory block.

The page buffer 23 may be coupled to the memory blocks through bit lines BL, exchange data with the selected memory block during program, read, and erase operations, and temporarily store transferred data.

The column decoder 24 may exchange data with the page buffer 23 in response to a column address CADD.

The input/output circuit 25 may transfer a command signal CMD and an address ADD from an external device to the control circuit 130, transfer externally provided data DATA to the column decoder 24, and transfer the data DATA from the column decoder 24 to an external device or the control circuit 130.

The control circuit 130 may control the circuit group 120 in response to the command signal CMD and the address ADD. During a soft program operation subsequent to a block erase operation, the control circuit 130 may control the circuit group 120 to program a first cell by applying the program voltage to a first line coupled to the first cell, verify a second cell adjacent to the first cell by applying a verify voltage to a second line coupled to the second cell, and repeat programming of the first cell and verifying the second cell until the verifying of the second cell passes. For example, the control circuit 130 may program dummy cells (first cells) included in the selected memory block after an erase operation of the selected memory block is completed. The control circuit 130 may control the circuit group 120 to perform a verify operation by using selection transistors (second cells) adjacent to the dummy cells (first cells) while programming the dummy cells (first cells). In other words, the control circuit 130 may control the circuit group 120 to increase threshold voltages of the dummy cells (first cells) by applying the program voltage to dummy lines (first lines) coupled to the dummy cells (first cells) of the selected memory block, and verify the selection transistors (second cells) by applying the verify voltage to selection lines (second lines) coupled to the selection transistors (second cells), for example, drain selection transistors and source selection transistors, which are adjacent to the dummy cells (first cells) whose threshold voltages are increased. After the dummy cells (first cells) are programmed, the adjacent selection transistors (second cells) may be verified for the following reasons.

When the program voltage is applied to the dummy lines (first lines), electrons may tunnel into or be trapped in the dummy cells (first cells), so that threshold voltages of the dummy cells (first cells) may be increased. When electrons exist in the dummy cells (first cells), the electrons in a channel under the selection transistors (second cells) may move away from the selection transistors (second cells) due to a repulsive force between the same electrons. Therefore, when the verify voltage is applied to the selection lines (second lines), since electrons do not gather under the selection transistors (second cells), a threshold voltage of the selection transistors (second cells) may appear to be relatively high. In other words, by controlling the amount of electrons tunneling into or trapped in the dummy cells (first cells), the amount of electrons under the adjacent selection transistors (second cells) may be equalized. Therefore, potentials of the selection transistors (second cells) included in different cell strings may be controlled to be the same as each other.

The above-described program method of the dummy cells is applicable to both two-dimensional and three-dimensional nonvolatile memory devices. Both nonvolatile memory devices are described blow in detail.

FIG. 2 is a circuit diagram illustrating a two-dimensional memory cell string.

Referring to FIG. 2, the two-dimensional nonvolatile memory device may include two-dimensionally structured memory cell strings. FIG. 2 illustrates one of the plurality of cell strings.

The cell string may be coupled between the common source line SL and the bit line BL, and include a source selection transistor SST, first and second dummy cells DC1 and DC2, memory cells C1 to C6, third and fourth dummy cells DC3 and DC4, and a drain selection transistor DST coupled in series in a longitudinal direction (X direction). In FIG. 2, the source selection transistor SST, the first to fourth dummy cells DC1 to DC4, the memory cells C1 to C6 and the drain selection transistor DST have been simplified for clarity. The number of elements may vary depending on the type of nonvolatile memory device. A gate of the source selection transistor SST may be coupled to the source selection line SSL. Gates of the first to fourth dummy cells DC1 to DC4 may be coupled to first to fourth dummy lines DL1 to DL4, respectively. Gates of the memory cells C1 to C6 may be coupled to word lines WL1 to WL6, respectively. The gate of the drain selection transistor DST may be coupled to the drain selection line DSL. The first to fourth dummy cells DC1 to DC4 may not store substantial data, and may complement the operations (program, read or erase) of the memory device.

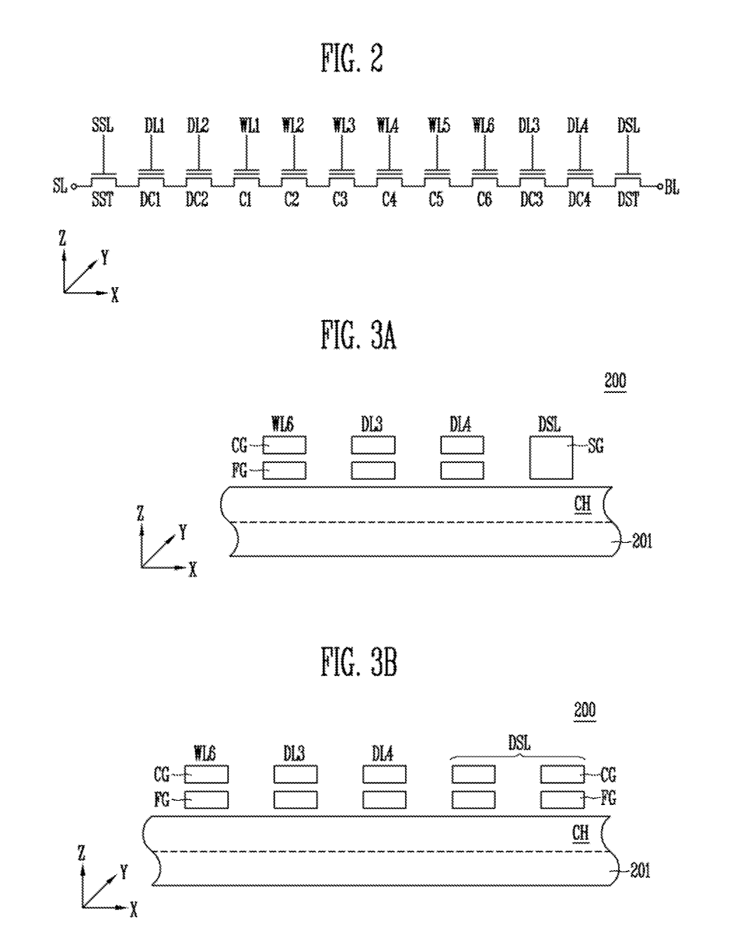

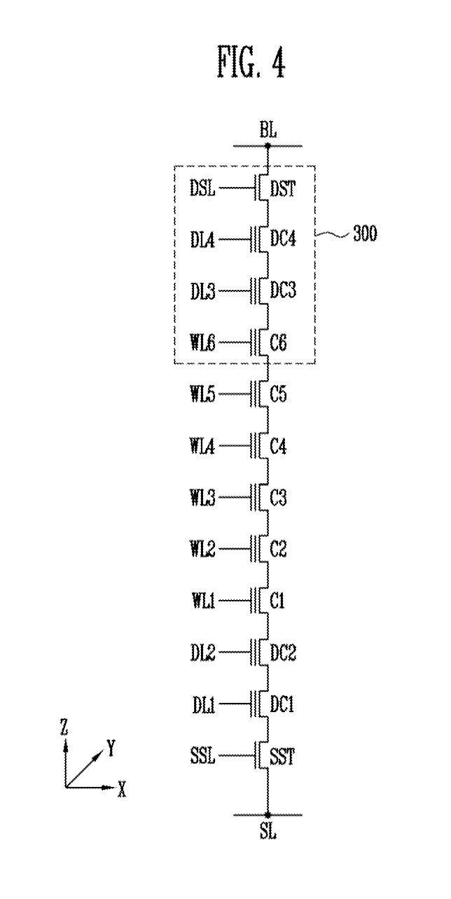

Among the above-described elements, the source and drain selection transistors SST and DST may be embodied in various structures. The source and drain selection transistors SST and DST may be described in detail with reference to FIGS. 3A and 3B.

FIGS. 3A and 3B are cross-sectional views illustrating the memory cell string shown in FIG. 2. The source and drain selection lines SSL and DSL may have substantially the same configuration. A region (200) where the drain selection line DSL is formed will be described with reference to the cross-sectional view for clear explanation.

Referring to FIG. 3A, the drain selection line DSL may be formed over a substrate 201, and dummy lines DL3 and DL4 may be formed between the drain selection line DSL and the word line WL6. Each of the memory cells and the dummy cells coupled between the word line WL6 and the dummy lines DL3 and DL4 may include a floating gate FG and a control gate CG that are separated from each other and stacked on top of each other. The drain selection transistor coupled to the drain selection line DSL may include a select gate SG formed of a conductive material. When a positive voltage is applied to the word line WL6, the dummy lines DL3 and DL4 and the drain selection line DSL formed over the substrate 201, electrons may gather at the upper portion of the substrate 201, so that a channel CH may be formed.

Referring to FIG. 3B, the word line WL6 and the dummy lines DL3 and DL4 may be the same as described above with reference to FIG. 3A, and the drain selection transistor coupled to the drain selection line DSL may have substantially the same structure as the dummy cells or the memory cells. For example, each of the memory cells or the dummy cells of the two-dimensional nonvolatile memory device may include the floating gate FG and the control gate CG separated from each other. However, the drain selection transistor may also include the floating gate FG and the control gate CG separated from each other. When the drain selection transistor has the same size as the dummy cells or the memory cells, a plurality of drain selection transistors may be grouped in order to perform an on/off operation as a switching device. By applying the same voltage to the drain selection lines coupled to the respective drain selection transistors, the plurality of drain selection transistors may operate as a single drain selection transistor.

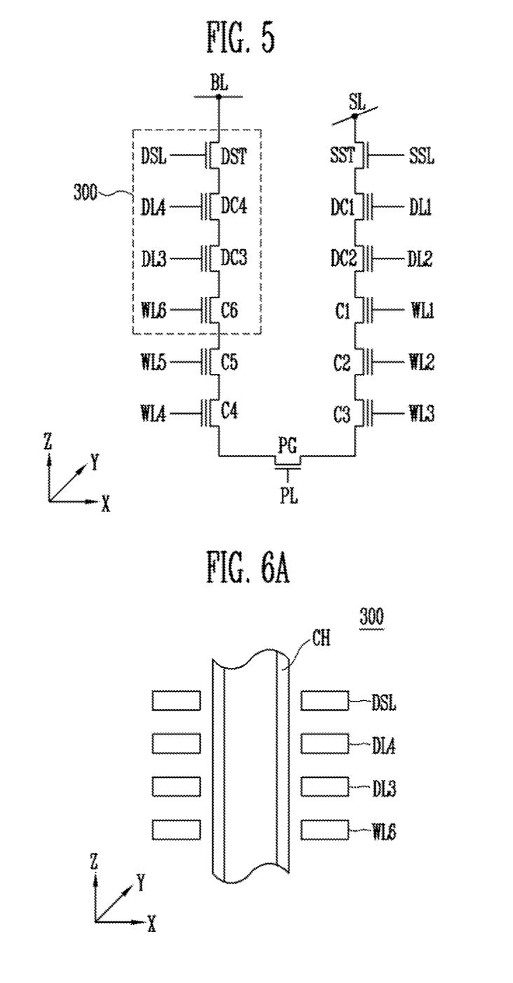

FIG. 4 is a circuit diagram illustrating a three-dimensional memory cell string according to an embodiment of the present invention.

Referring to FIG. 4, the three-dimensional memory cell string according to an embodiment may include an I-shaped cell string coupled in a vertical direction (Z direction) to a substrate. For example, the source line SL may be coupled to a lower portion of the cell string, and the bit line BL may be coupled to an upper portion of the cell string. The cell string may include the source selection transistor SST, the first and second dummy cells DC1 and DC2, the plurality of memory cells C1 to C6, the third and fourth dummy cells DC3 and DC4 and the drain selection transistor DST, which are coupled in series between the source line SL and the bit line BL.

The gate of the source selection transistor SST may be coupled to the source selection line SSL. The gates of the first and second dummy cells DC1 and DC2 may be coupled to the first and second dummy lines DL1 and DL2, respectively. The gates of the first to sixth memory cells C1 to C6 may be coupled to the first to sixth word lines WL1 to WL6, respectively. The gates of the third and fourth dummy cells DC3 and DC4 may be coupled to the third and fourth lines DL3 and DL4, respectively. The gate of the drain selection transistor DST may be coupled to the drain selection line DSL.

For a clearer explanation, FIG. 4 illustrates the six memory cells C1 to C6, the four dummy cells DC1 to DC4, the one source selection transistor SST, and the one drain selection transistor DST. However, more memory cells, more dummy cells, more source selection transistors and more drain selection transistors may be included according to memory devices. The first to fourth dummy cells DC1 to DC4 may not store substantial data, and may complement the operations (program, read or erase) of the memory devices.

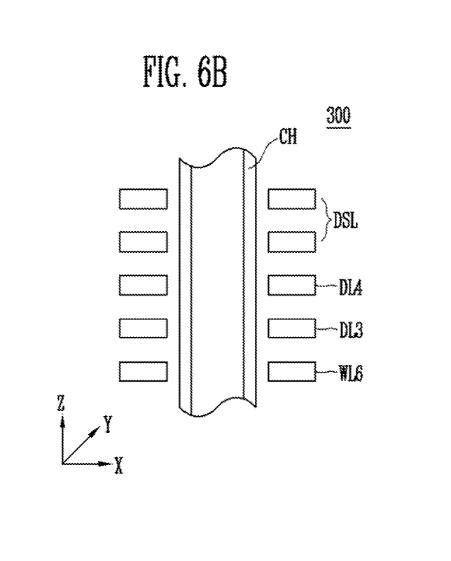

FIG. 5 is a circuit diagram illustrating a three-dimensional memory cell string according to another embodiment of the present invention.

Referring to FIG. 5, the memory device according to another embodiment may include a U-shaped cell string coupled in a vertical direction (Z direction) to a substrate. For example, a first cell string may be coupled between the source line SL and the pipe gate PG, a second cell string may be formed between the bit line BL and the pipe gate PG, and a pair of the first and second cell strings may be coupled through the pipe gate PG so that the U-shaped cell string may be formed. Therefore, the pipe gate PG may be coupled to lower portions of the first and second cell strings, the source line SL may be coupled to an upper portion of the first cell string, and the bit line BL may be coupled to an upper portion of the second cell string. The first cell string may include the source selection transistor SST, the first and second dummy cells DC1 and DC2 and the memory cells C1 to C3, which are coupled in series between the source line SL and the pipe gate PG. The second string may include the memory cells C5 to C8, the third and third dummy cells DC3 and DC4 and the drain selection transistor DST, which are coupled in series between the pipe gate PG and the bit line BL.

The gate of the source selection transistor SST may be coupled to the source selection line SSL. The gates of the first and second dummy cells DC1 and DC2 may be coupled to the first and second dummy lines DL1 and DL2, respectively. The gates of the first to third memory cells C1 to C3 may be coupled to the first to third word lines WL1 to WL3, respectively. The gates of the fourth to sixth memory cells C4 to C6 may be coupled to the fourth to sixth word lines WL4 to WL6, respectively. The gates of the third and fourth dummy cells DC3 and DC4 may be coupled to the third and fourth dummy lines DL3 and DL4, respectively. The gate of the drain selection transistor DST may be coupled to the drain selection line DSL.

For a clearer explanation, FIG. 5 illustrates the six memory cells C1 to C6, the four dummy cells DC1 to DC4, the one source selection transistor SST and one drain selection transistor DST. However, more memory cells, more dummy cells, more source selection transistors and more drain selection transistors may be included. The first to fourth dummy cells DC1 to DC4 may not store substantial data, and may complement the operations (program, read or erase) of memory devices.

Cross-sections of the elements described above will now be described in detail with reference to FIGS. 4 and 5.

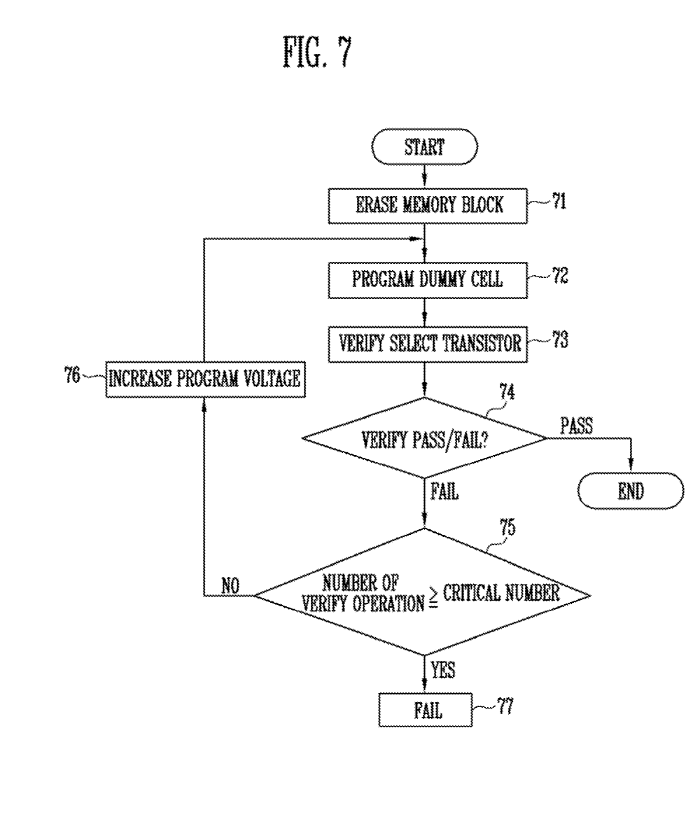

FIGS. 6A and 6B are cross-sectional views illustrating the memory cell string shown in FIGS. 4 and 5. The source and drain selection lines SSL and DSL have substantially the same configuration as each other. A region (300) where the drain selection line DSL is formed in the structure of the memory cell string will now be described.

Referring to FIG. 6A, the three-dimensionally structured cell string may include the vertical channel layer, which is formed in the vertical direction (Z direction) to the substrate 201 and forming the channel CH during the program, read or erase operation, the drain selection line DSL, which surrounds the vertical channel layer, and the fourth dummy line DL4, the third dummy line DL3 and the word line WL6, which are located under and sequentially separated from the drain selection line DSL.

Referring to FIG. 6B, the three-dimensionally structured cell string may include the vertical channel layer, which is formed in the vertical direction (Z direction) to the substrate 201 and forming the channel CH during the program, read or erase operation, the drain selection line DSL, which surrounds the vertical channel layer, and the fourth dummy line DL4, the third dummy line DL3 and the word line WL6, which are located under and sequentially separated from the drain selection line DSL. The drain selection line DSL may include a plurality of grouped selection lines.

A method of operating a nonvolatile memory device including the above-described two-dimensional or three-dimensional structure is described below.

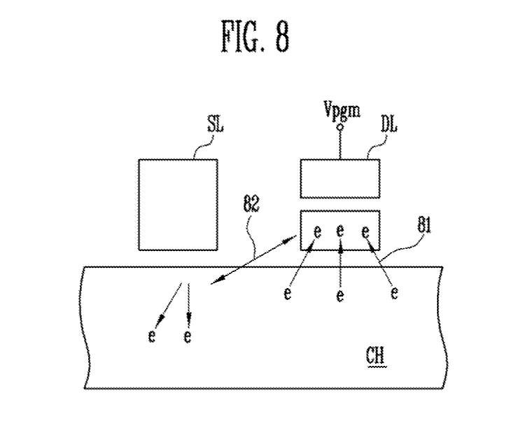

FIG. 7 is a flowchart illustrating an operating method of a semiconductor device according to an embodiment of the present invention.

Referring to FIG. 7, an erase operation may be performed on a selected memory block (71). For example, the control circuit 130 may select one of the memory blocks included in the memory cell array 110, as shown in FIG. 1. The circuit group 120 shown in FIG. 1 may be controlled to erase all dummy cells and all memory cells included in the selected memory block. The erase operation of the selected memory block may be performed in an Incremental Step Pulse Erase (ISPE) scheme.

When the erase operation of the selected memory block is completed, the dummy cells of the selected memory block may be programmed (72). The dummy cells may be programmed in a soft program operation in which threshold voltages of the erased memory cells may be increased in an erase period after the block erase operation. By applying a program voltage to a dummy line adjacent to the selection line without directly applying the program voltage to the selection line, and by performing the verify operation to the selection transistors, potentials of the selection transistors may increase. In other words, the operating method in accordance with an embodiment of the present invention may program the dummy cells instead of directly programming the selection transistors in order to increase the potentials of the selection transistors.

More specifically, threshold voltages of the dummy cells may be increased by applying a program voltage to dummy lines coupled to the dummy cells (72). As illustrated in FIG. 2, when the plurality of dummy cells DC1 to DC4 are adjacent to the drain and source selection transistors DST and SST, all dummy cells DC1 to DC4 may be programmed or only the dummy cells DC1 and DC4 directly adjacent to the drain and source selection transistors DST and SST, respectively, may be programmed. In other words, the dummy cells including the dummy cells DC1 and DC4 directly adjacent to the drain and source selection transistors DST and SST may be programmed. After the dummy cells are programmed by applying the program voltage to the dummy lines for a predetermined period of time, selection transistors adjacent to the dummy cells may be verified (73).

Programming the dummy cells and verifying adjacent selection transistors will be described with reference to FIG. 8.

FIG. 8 is a schematic view illustrating the movement of electrons during a program operation of dummy cells according to an embodiment of the present invention.

FIG. 8 exemplarily shows a nonvolatile memory device including a floating gate among two-dimensionally structured nonvolatile memory devices. The present invention is applicable to a three-dimensionally structured nonvolatile memory device, or a SONOS (silicon/oxide/nitride/oxide/silicon), MANOS (metal/Al₂O₃/nitride/oxide/silicon) or TANOS (TaN/Al₂O₃/nitride/oxide/silicon) nonvolatile memory device.

When the program voltage Vpgm is applied to a dummy line DL, electrons (e) may gather on the surface of the substrate located under the dummy cell, and form the channel CH. Some electrons (e) may tunnel from the channel CH to the floating gate of the dummy cell (81) so that the threshold voltage of the dummy cell may increase. When the electrons (e) flow into the floating gate of the dummy cell, a repulsive force may be generated between the electrons (82). As a result, the density of the electrons (e) gathering in the channel CH under the selection line SL may be reduced. When the density of the electrons (e) in the channel CH is reduced less than a predetermined density, the channel CH in the corresponding area may be blocked. In other words, the channel CH may not be formed under the selection line SL. Therefore, when the selection transistor is verified by applying a verify voltage to the selection line SL, although the electrons (e) do not actually tunnel into or are not trapped in the selection transistor, the potential of the selection transistor may appear to be increased. In other words, the density of the electrons (e) in the channel CH under the selection transistor is in inverse proportion to the potential of the selection transistor. Therefore, as the density of the electrons (e) in the channel CH under the selection transistor becomes lower, the verify voltage level increases. Thus, the verify operation of the selection transistor may pass or fail, depending on the density of the electrons (e) in the channel CH. For example, when the channel CH is formed under the selection line SL because of the high density of the electrons (e), the verify operation may be determined as a fall. When the channel CH is not formed under the selection line SL due to the low density of the electrons (e), the verify operation may be determined as a pass. The verify voltage may differ between memory devices since memory devices have different electrical characteristics.

Referring again to FIG. 7, it may be determined whether the verify operation of the selection transistor is a pass or a fail (74). The verify operation of the selection transistors may be performed by applying a verify voltage to selection lines coupled to selection transistors. A pass voltage may be applied to the dummy lines and the word lines.

When the verify operation passes, the program operation of the dummy cells may be terminated since the potentials of the selection transistors are sufficiently increased.

When the verify operation fails, it may be determined that the potentials of the selection transistors are not sufficiently increased, and the number of verify operations performed on the selection transistors may be compared with a critical number (75). The number of verify operations may be counted as the number of times the verify voltage is applied to the selection line SL. The critical number may be set to the maximum number of times the corresponding memory device performs the verify operation. Therefore, the critical number may vary for each memory device.

After a result of comparing the number of verify operations with the critical number (75), when the number of verify operations is greater than or equal to the critical number, the program operation of the dummy cells may be determined as a fail (77).

After a result of comparing the number of verify operations with the critical number (75), when the number of verify operations is less than the critical number, the program voltage may be increased by a step voltage (76), and the program operation of the dummy cells may be resumed. In other words, steps ‘72’ to ‘76’ may be repeated until the verify operation of the selection transistors passes.

As described above, after an erase operation of the selected memory block is completed, dummy cells adjacent to selection transistors may be programmed without directly programming the selection transistors in order to increase the potentials of the selection transistors, and a verify operation may be performed on the selection transistors, so that the potentials of the selection transistors may be uniformly increased. When the potentials of the selection transistors are uniformly increased, the reliability of a sensing operation may be improved during a subsequent main program operation or read operation. Accordingly, reliability of the nonvolatile memory device may be improved.

The above-described semiconductor device may be used in the following system.

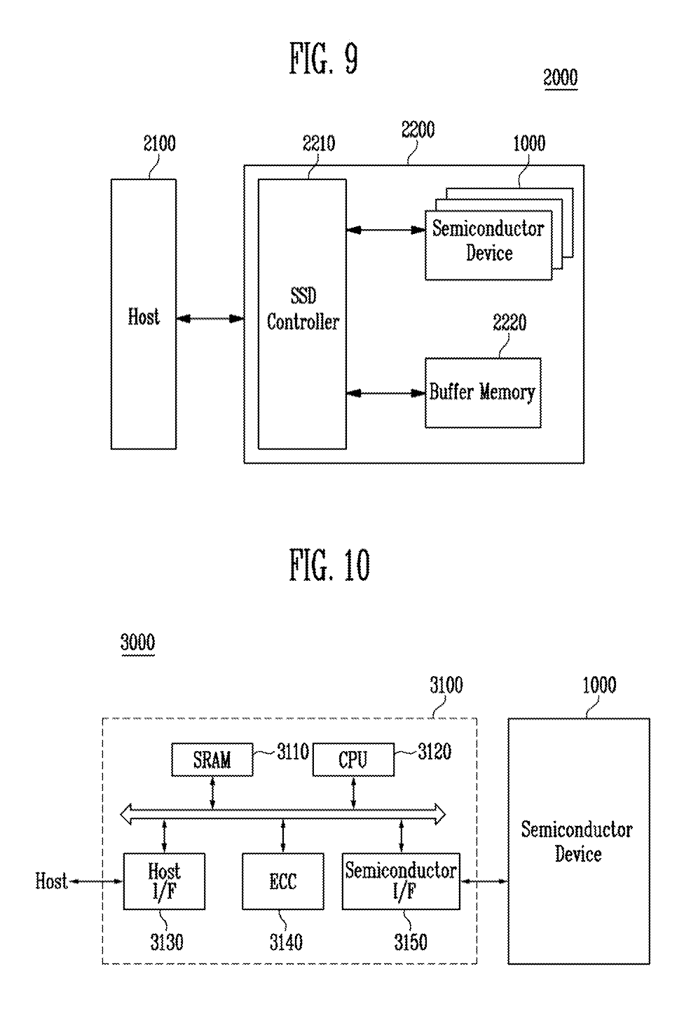

FIG. 9 is a block diagram illustrating a solid state drive including a semiconductor device according to an embodiment of the present invention.

Referring to FIG. 9, a drive device 2000 may include a host 2100 and an SSD 2200. The SSD 2200 may include an SSD controller 2210, a buffer memory 2220 and a semiconductor device 1000.

The SSD controller 2210 may provide a physical connection between the host 2100 and the SSD 2200. In other words, the SSD controller 2210 may perform interfacing with the SSD 2200 in response to a bus format of the host 2100. The SSD controller 2210 may decode a command provided from the host 2100. According to a decoding result, the SSD controller 2210 may access the semiconductor device 1000. As the bus format of the host 2100, Universal Serial Bus (USB), Small Computer System Interface (SCSI), Peripheral Component Interconnect Express (PCI-E), Advanced Technology Attachment (ATA), Parallel ATA (PATA), Serial ATA (SATA), and Serial Attached SCSI (SAS) may be included.

The buffer memory 2220 may temporarily store program data provided from the host 2100 or data read from the semiconductor device 1000. When a read request is made by the host 2100, if data in the semiconductor device 1000 is cached, the buffer memory 2220 may support a cache function to directly provide the cached data to the host 2100. In general, data transfer speed by the bus format (for example, SATA or SAS) of the host 2100 may be higher than the transfer speed of a memory channel of the SSD 2200. In other words, when an interface speed of the host 2100 is higher than the transfer speed of the memory channel of the SSD 2200, performance degradation caused by the speed difference may be minimized by providing a buffer memory 2220 having a large capacity. The buffer memory 2220 may be provided as Synchronous DRAM in order to provide sufficient buffering in the SSD 2200.

The semiconductor device 1000 may be provided as a storage medium of the SSD 2200. For example, the semiconductor device 1000 may be provided as a nonvolatile memory device having large storage capacity as described above in detail with reference to FIG. 1. The semiconductor device 1000 may be a NAND-type flash memory.

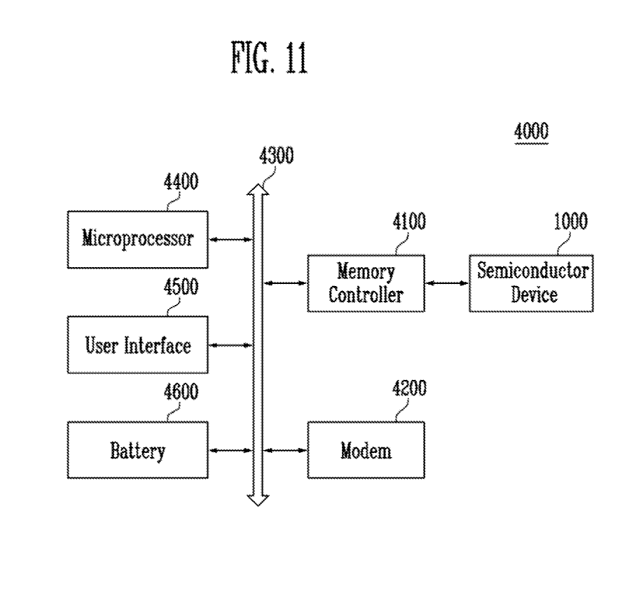

FIG. 10 is a block diagram illustrating a memory system including a semiconductor device according to an embodiment of the present invention.

Referring to FIG. 10, a memory system 3000 according to an embodiment may include a memory control unit 3100 and the semiconductor device 1000.

Since the semiconductor device 1000 may have substantially the same configuration as shown in FIG. 1, a detailed description thereof may be omitted.

The memory control unit 3100 may be configured to control the semiconductor device 1000. An SRAM 3110 may be used as a working memory of a CPU 3120. A host interface (I/F) 3130 may include a data exchange protocol of a host electrically coupled with the memory system 3000. An error correction circuit (ECC) 3140 in the memory control unit 3100 may detect and correct an error in data read from the semiconductor device 1000. A semiconductor I/F 3150 may interface with the semiconductor device 1000. The CPU 3120 may perform a control operation for data exchange of the memory control unit 3100. In addition, although not illustrated in FIG. 10, a ROM (not shown) for storing code data for interfacing with a host may be provided in the memory system 3000.

In an embodiment, the memory system 3000 may be applied to one of a computer, an Ultra Mobile PC (UMPC), a workstation, a net-book, a PDA, a portable computer, a web tablet, a wireless phone, a mobile phone, a smartphone, a digital camera, a digital audio recorder, a digital audio player, a digital picture recorder, a digital picture player, a digital video recorder, a digital video player, a device of transmitting and receiving information in a wireless environment, and various devices constituting a home network.

FIG. 11 is a block diagram illustrating a computing system 400 including a semiconductor device according to an embodiment of the present invention.

Referring to FIG. 11, the computing system 4000 includes an embodiment of a semiconductor device 1000 electrically coupled to a bus 4300, a memory controller 4100, a modem 4200, a microprocessor 4400, and a user interface 4500. When the computing system 4000 is a mobile device, a battery 4600 for supplying an operation voltage of the computing system 4000 may be additionally provided. The computing system 4000 may include an application chip set (not shown), a camera image processor (CIS) (not shown), a mobile DRAM (not shown), and the like.

The semiconductor device 1000 may be configured in substantially the same manner as the semiconductor device 1000 shown in FIG. 1. Thus, a detailed description thereof will be omitted.

The memory controller 4100 and the semiconductor device 1000 may be components of a Solid State Drive/Disk (SSD).

The semiconductor device 1000 and the memory controller 4100 may be mounted using various types of packages. For example, the semiconductor device 1000 and the memory controller 4100 may be mounted using packages such as Package on Package (PoP), Ball Grid Arrays (BGAs), Chip Scale Packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flat Pack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-level Processed Stack Package (WSP), and the like.

According to embodiments of the present invention, the reliability of program, read and erase operations of a semiconductor device may be improved by equalizing electrical characteristics of selection transistors included in a semiconductor device.

1. A method of operating a semiconductor device, the method comprising:
programming a first cell;
verifying a second cell adjacent to the first cell; and
repeating the programming of the first cell, and the verifying of the second cell until the verifying of the second cell passes,
wherein a threshold voltage of the second cell is increased by performing the programming the first cell.

2. The method of claim 1, wherein the programming of the first cell is performed by applying a program voltage to a first line coupled to the first cell.

3. The method of claim 1, wherein the verifying of the second cell is performed by applying a verify voltage to a second line coupled to the second cell.

4. The method of claim 3, wherein the verifying of the second cell is performed by applying a pass voltage to a first line coupled to the first cell.

5. The method of claim 1, wherein a program voltage for the programming of the first cell is gradually increased whenever the programming of the first cell and the verifying of the second cell are repeated.

6. A method of operating a semiconductor device including a memory block having a plurality of cell strings comprising dummy cells coupled between selection transistors and memory cells, the method comprising:
programming the dummy cells when an erase operation on the memory block is completed;
verifying the selection transistors; and
repeating the programming of the dummy cells, and the verifying of the selection transistors until the verifying of the selection transistors passes,
wherein a threshold voltage of the selection transistor is increased by performing the programming the dummy cells.

7. The method of claim 6, wherein the programming of the dummy cells is performed by applying a program voltage to dummy lines coupled to the dummy cells.

8. The method of claim 6, wherein the verifying of the selection transistors is performed by applying a verify voltage to selection lines coupled to the selection transistors.

9. The method of claim 8, wherein the verifying of the selection transistors is performed by applying a pass voltage to dummy lines coupled to the dummy cells, and word lines coupled to the memory cells.

10. The method of claim 6, further comprising comparing a number of times of the verifying of the selection transistors with a critical number.

11. The method of claim 10, wherein the critical number is set to a maximum number of times of the verifying of the selection transistors.

12. The method of claim 10, wherein a program operation of the dummy cells is determined as a fail when the number of times of the verifying of the selection transistors is greater than or equal to the critical number, or
the programming of the dummy cells and the verifying of the selection transistors are repeated until the verifying of the selection transistors passes when the number of times of the verifying of the selection transistors is less than the critical number.

13. The method of claim 6, wherein a program voltage for the programming of the first cell is gradually increased whenever the programming of the dummy cells and the verifying of the selection transistors are repeated.

14. A method of operating a semiconductor device including a memory block having a plurality of cell strings comprising dummy cells coupled between selection transistors and memory cells, the method comprising:
performing an erase operation on the memory block;
performing a program operation on the dummy cells to trap electrons of the dummy cells;
performing a verify operation on the selection transistors; and
repeating the performing the program operation on the dummy cells and the performing of the verify operation until the verify operation passes,
wherein a density of the electrons in a channel region adjacent to the selection transistors is reduced by performing the program operation on the dummy cells.

15. The method of claim 14, wherein the electrons in the channel region adjacent to the selection transistors are pushed away from the channel region by a repulsive force with the trapped electrons of the dummy cells.

16. The method of claim 15, wherein the programming of the dummy cells is performed by applying a program voltage to dummy lines coupled to the dummy cells.

17. The method of claim 16, wherein a program voltage for the program operation on the dummy cells gradually increased whenever the verify operation on the selection transistors is repeated.

18. The method of claim 14, wherein the verify operation is performed by applying a verify voltage to selection lines coupled to the selection transistors.

19. The method of claim 18, further comprising comparing a number of times of the verify operations with a critical number.

20. The method of claim 19, wherein the verify operation is determined as a fail when the number of times the verify operation greater than or equal to the critical number, or
the program operation and the verify operation on the selection transistors are repeated until the verify operation passes when the number of times of the verify operation is less than the critical number.
